(19) United States
(12) Patent Application Publication
(10) Pub. No.: US 2014/0178814 A1
(43) Pub. Date: Jun. 26, 2014

(54) DRY FILM PHOTORESIST HAVING OXYGEN PERMEABLE BARRIER LAYER AND MANUFACTURING METHOD THEREOF

(71) Applicant: SAMSUNG ELECTRO-MECHANICS CO. LTD., (US)

(72) Inventors: Hyo Jin YOON, Suwon (KR); Hye Jin CHO, Suwon (KR); Ji Eun JEON, Suwon (KR); Sung Hee LIM, Suwon (KR); Suk Jin HAM, Suwon (KR)

(73) Assignee: SAMSUNG ELECTRO-MECHANICS CO., LTD., Suwon (KR)

(21) Appl. No.: 13/794,099

(22) Filed: Mar. 11, 2013

(30) Foreign Application Priority Data
Dec. 21, 2012 (KR) 10-2012-0150308

(51) Int. Cl. G03F 7/09

(52) U.S. Cl. CPC G03F 7/092
USPC 430/273.1; 430/271.1

(57) ABSTRACT

There is provided a dry film photoresist including: a base film having an oxygen permeable barrier layer formed thereon; a photosensitive resin layer formed on the oxygen permeable barrier layer; and a protective film formed on the photosensitive resin layer. According to the present invention, the dry film photoresist includes the oxygen permeable barrier layer formed on the base film to prevent a curing reaction from being deteriorated by oxygen permeation in the dry film photoresist, such that residue that is not peeled off may be decreased, thereby significantly decreasing process defects.

### CROSS-REFERENCE TO RELATED APPLICATIONS

This application claims the priority of Korean Patent Application No. 10-2012-0150308 filed on Dec. 21, 2012, in the Korean Intellectual Property Office, the disclosure of which is incorporated herein by reference.

### BACKGROUND OF THE INVENTION

1. Field of the Invention

The present invention relates to a dry film photoresist having an oxygen permeable barrier layer and a manufacturing method thereof.

2. Description of the Related Art

Since dry film photoresist was developed by Du Pont in the United States in 1968 under the brand name ‘RISTON’, dry film photoresist has been an important material for use in the electrical and electronics industries, particularly, in the processing of printed circuit boards, and the like.

Among photoresist materials used to form a circuit on a printed circuit board, photosensitive ink for screen printing accounts for about 50% thereof. However, during manufacturing a double sided or multi-layer printed circuit board requiring high density and a high degree of reliability, dry film photoresist has necessarily been used.

Dry film photoresist, as described above, has a structure in which two layers, that is, a base film and a photosensitive resin layer are laminated, and further includes a protective film in order to protect the photosensitive resin layer until the dry film photoresist is used.

Generally, as a base film, a polyester film such as polyethylene terephthalate is used. This base film, which serves as a support for the photosensitive resin layer during manufacturing of the dry film photoresist, facilitates handling during exposure of the photosensitive resin layer having adhesive properties.

Photosensitive resin may be divided into negative-type photosensitive resin and positive-type photosensitive resin according to reaction mechanism when exposed to light. In the case of negative type photosensitive resin, a photo-crosslinking reaction occurs in an exposed portion, and an unexposed portion is washed and removed by alkali, such that a resist pattern remains. In the case of positive type photosensitive resin, a photo-degradation reaction occurs in an exposed portion to thereby be developed by alkali, and an unexposed portion remains to form a resist pattern.

The photosensitive resin layer includes a photo-polymerizable monomer, a photo-polymerization initiator, a polymer binder, or the like, to thereby be manufactured so as to correspond to a use purpose, and this photosensitive resin layer is applied to the base film. This photosensitive resin layer has various compositions according to the mechanical and chemical properties required for photoresist and conditions for processing, or the like.

Meanwhile, the protective film, which serves as a protective cover preventing damage to the photoresist during handling and protecting the photosensitive resin layer from foreign objects such as dust, is laminated on a back surface of the photosensitive resin layer on which the base film is not formed.

Generally, in the case of the dry film photoresist having the configuration as described above, a portion of the dry film that is not peeled off may remain on a surface of a substrate as residue during exposure, thereby causing process and product defects.

In addition, during measuring and evaluating the degrees of curing of upper and lower portions of the dry film using Fourier transform-infrared spectroscopy (FT-IR), it may be seen that there is a difference in the degree of curing between the lower portion of the dry film in which the base film is present and the upper portion of the dry film in which the protective film is present. This may be caused by a difference in oxygen-permeability between the base film and the protective film.

Therefore, in order to solve this problem, an oxygen permeable barrier layer is provided on the base film, such that the degrees of curing of the upper and lower portions of the dry film may be improved.

### RELATED ART DOCUMENT

(Patent Document 1) Korean Patent Laid-open Publication No. 2009-0010797
(Patent Document 2) Korean Patent Laid-open Publication No. 2011-0134398

### SUMMARY OF THE INVENTION

An aspect of the present invention provides a dry film photoresist capable of improving the degrees of curing of upper and lower portions of the dry film photoresist by forming an oxygen permeable barrier layer on a base film.

According to an aspect of the present invention, there is provided a dry film photoresist including: a base film having an oxygen permeable barrier layer formed thereon; a photosensitive resin layer formed on the oxygen permeable barrier layer; and a protective film formed on the photosensitive resin layer.

Oxygen permeability of the oxygen permeable barrier layer may be less than 0.1.

The oxygen permeable barrier layer may be formed of diamond-like carbon (DLC).

The oxygen permeable barrier layer may be formed of ethylene vinyl acetate (EVA).

The base film may be formed of polyethylene (PE).

The photosensitive resin layer may include at least one selected from a group consisting of a polymer binder, a monomer, a photo-initiator, a thermal polymerization inhibitor, a polymerization accelerator, and a plasticizer.

The protective film may be formed of polyethylene terephthalate (PET).

According to another aspect of the present invention, there is provided a manufacturing method of a dry film photoresist, the manufacturing method including: forming an oxygen permeable barrier layer on abase film; and sequentially forming a photosensitive resin layer and a protective film on the oxygen permeable barrier layer.

Oxygen permeability of the oxygen permeable barrier layer may be less than 0.1.

The forming of the oxygen permeable barrier layer may be performed by a deposition method.

The oxygen permeable barrier layer may be formed of diamond-like carbon (DLC).

The oxygen permeable barrier layer may be formed of ethylene vinyl acetate (EVA).

The EVA may be formed by an adhesion method or an extrusion method.

The adhesion method may be performed using poly dimethyl siloxane (PDMS) or siloxane.

The base film may be formed of polyethylene (PE).

The photosensitive resin layer may include at least one selected from a group consisting of a polymer binder, a monomer, a photo-initiator, a thermal polymerization inhibitor, a polymerization accelerator, and a plasticizer.

The protective film may be formed of polyethylene terephthalate (PET).

### BRIEF DESCRIPTION OF THE DRAWINGS

The above and other aspects, features and other advantages of the present invention will be more clearly understood from the following detailed description taken in conjunction with the accompanying drawings, in which:

FIG. 1 is a cross-sectional view of a laminate structure of a dry film photoresist according to an embodiment of the present invention;

FIG. 2 is a cross-sectional view of a laminate structure of a dry film photoresist according to another embodiment of the present invention; and

FIG. 3 is a flowchart showing a manufacturing method of a dry film photoresist according to an embodiment of the present invention.

### DETAILED DESCRIPTION OF THE EMBODIMENTS

Hereinafter, embodiments of the present invention will be described in detail with reference to the accompanying drawings.

The invention may, however, be embodied in many different forms and should not be construed as being limited to the embodiments set forth herein. Rather, these embodiments are provided so that this disclosure will be thorough and complete, and will fully convey the scope of the invention to those skilled in the art.

In the drawings, the thicknesses of layers and regions are exaggerated for clarity, and the same reference numerals will be used throughout to designate the same or like elements.

A dry film photoresist 100 according to an embodiment of the invention may include a base film having an oxygen permeable barrier layer 20 formed thereon; a photosensitive resin layer 30 formed on the oxygen permeable barrier layer 20; and a protective film 40 formed on the photosensitive resin layer 30.

As the base film 10, a polyethylene film may be mainly used due to advantages such as cost, flexibility, strength, hardness, or the like. The base film 10, which serves as a support for the photosensitive resin layer 30 during manufacturing of the dry film photoresist 100, may facilitate handling during exposure of the photosensitive resin layer 30 having adhesion.

The photosensitive resin layer 30 may include a polymer binder, a monomer, a photo-initiator, a thermal polymerization inhibitor, a polymerization accelerator, a plasticizer, or the like, be applied to the oxygen permeable barrier layer 20, have an appropriate thickness so as to correspond to a use purpose, and have various compositions according to the required mechanical and chemical properties and conditions for processing, or the like.

The protective film may mainly be formed of a polyester based material, particularly, polyethylene terephthalate. In addition, the protective film, which serves as a protective cover preventing damage of the dry film photoresist 100 during handling and protecting the photosensitive resin layer 30 from foreign objects such as dust, may be laminated on a back surface of the photosensitive resin layer 30 on which the base film 10 is not formed.

Generally, dry film photoresist may be used to form a pattern by removing a base film, laminating a photosensitive resin layer on a substrate while applying heat and pressure thereto so as to be closely adhered to the substrate, exposing a protective film to light, and then removing the protective film. At this time, a portion of the dry film photoresist that is not peeled off may remain on a surface of the substrate as residue, thereby causing process and product defects.

In addition, when the degrees of curing of upper and lower portions of the dry film resist are measured and evaluated using a Fourier transform-infrared spectroscopy (FT-IR), it may be seen that there is a difference in the degree of curing between the lower portion in which the base film is present and the upper portion in which the protective film is present.

That is, the degree of curing of the lower portion in which the base film is present is lower than that of the upper portion by 20 to 30% on average under the same conditions, such that the residue remains on the surface of the substrate. This difference in the degree of curing may be caused by a difference in oxygen-permeability between the base film and the protective film.

Generally, oxygen may act as a radical oxygen scavenger on a radical and an oligomer radical formed by an initiation reaction to remove radical activity and delay a polymerization rate. In addition, oxygen in the dry film photoresist 100 may react with the radical during initial exposure, such that a predetermined amount of oxygen is consumed. Then, the radical may explosively generate the polymerization reaction. That is, oxygen may have an important influence on a reaction rate or the degree of curing in a photo-polymerization reaction.

In addition, in order to confirm a possibility of non-curing in a case in which a photo initiator close to an exposed surface absorbs ultraviolet (UV) light and thus an intensity of UV light arriving at a lower surface contacting the substrate becomes insufficient, when the degree of curing was evaluated by exposing the base film instead of the protective film of the dry film photoresist to light, the average degree of curing of the base film was 52%, and the average degree of curing of the protective film was 84%.

That is, it may be appreciated that the degree of curing of a lower region of the base film is lower than that of an upper region of the protective film by 25% or more on average, regardless of an exposure direction. Therefore, it may be determined that the possibility of non-curing due to insufficient intensity of the UV light arriving at the lower region is low.

In order to identify a cause of the difference in the degrees of curing between the upper and lower portions of the dry film photoresist, a test for measuring oxygen permeability of the protective film and the base film was conducted in advance. The test was performed by measuring amounts of oxygen permeated through the protective film and the base film in a film region of 1 m×1 m in atmospheric conditions of 21% oxygen for 24 hours.

As a result of measuring the oxygen permeability by the above-mentioned method, an average oxygen permeability of polyethylene (PE) used as the base film was 2382.7 cc/m²⁻day, and an average oxygen permeability of polyethylene terephthalate (PET) used as the protective film was 23.0 cc/m²⁻day. Therefore, it maybe appreciated that the oxygen permeability of polyethylene (PE) is about 100 times higher than that of polyethylene terephthalate (PET).

Since the oxygen permeability of polyethylene (PE) is significantly higher than that of polyethylene terephthalate (PET), the average degree of curing of the polyethylene (PE) during exposure may be affected by oxygen as the polymerization inhibitor to thereby be decreased.

Therefore, in order to observe a curing behavior of the dry film photoresist in a decreased-oxygen environment, a test for evaluating the degree of curing of the dry film photoresist was conducted in an atmosphere in which a concentration of oxygen is ⅕ or less that of oxygen in the air.

As a result, the average degree of curing of polyethylene terephthalate (PET) was almost unchanged, but the average degree of curing of polyethylene (PE) was increased by 10 to 15% in the environment in which the concentration of oxygen was decreased.

As a result, it may be appreciated that the average degree of curing of polyethylene was lowered due to oxygen serving as a polymerization inhibitor.

Therefore, according to the embodiment of the present invention, in order to overcome the difference in the degrees of curing between the upper and lower portions of the dry film photoresist 100, the oxygen permeable barrier layer 20 may be formed on the base film 10, such that adhesive properties and release properties may be maintained, and the degree of curing of the lower portion of the dry film photoresist 100 may be improved.

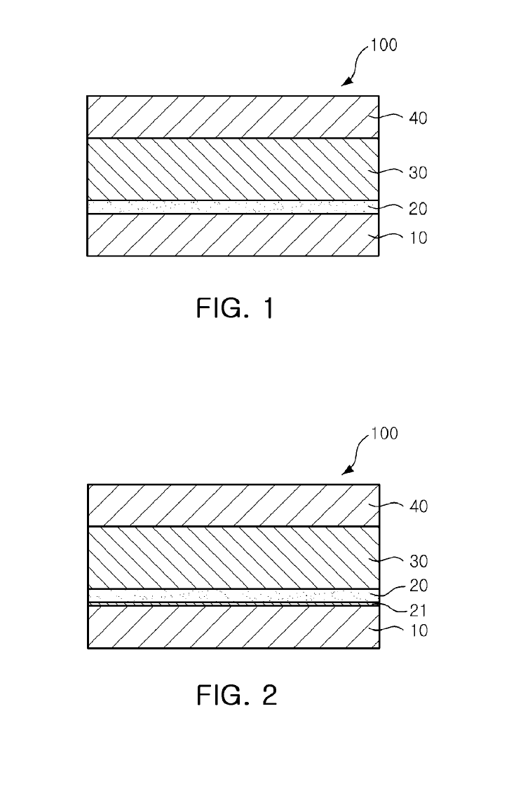

FIG. 1 is a cross-sectional view of a laminate structure of a dry film photoresist 100 according to an embodiment of the present invention.

The dry film photoresist 100 may include a base film 10 having an oxygen permeable barrier layer 20 formed thereon; a photosensitive resin layer 30 formed on the oxygen permeable barrier layer 20; and a protective film 40 formed on the photosensitive resin layer 30 as shown in FIG. 1.

Here, oxygen permeability of the oxygen permeable barrier layer 20 may be less than 0.1 but higher than 0. That is, there is no lowest limit of oxygen permeability, but when the oxygen permeability is 0.1 or more, the initiator may be transformed by oxygen to thereby affect the degree of curing.

Since diamond-like carbon (DLC), an amorphous carbon compound used as the oxygen permeable barrier layer 20, has high oxygen barrier properties and is an inactive material, DLC is not transformed according to external conditions, has abrasion resistance, photo permeable properties, electrical insulating properties, and the like, and is currently used for various industrial purposes.

Ethylene vinyl acetate (EVA) used as the oxygen permeable barrier layer 20 is a material having high oxygen barrier properties.

As described above, in the case in which the oxygen permeable barrier layer 20 is formed on the base film 10, the oxygen permeable barrier layer may prevent a curing reaction from being deteriorated by oxygen permeation through the dry film photoresist 100, such that the residue that is not peeled off may be decreased, thereby significantly decreasing process defects.

FIG. 2 is a cross-sectional view of a laminate structure of a dry film photoresist 100 according to an embodiment of the present invention.

The dry film photoresist 100 may include a base film 10 having an oxygen permeable barrier layer 20 formed thereon; a photosensitive resin layer 30 formed on the oxygen permeable barrier layer 20; and a protective film 40 formed on the photosensitive resin layer 30, and may further include an adhesive layer 21 between the oxygen permeable barrier layer 20 and the base film 10 as shown in FIG. 2.

Here, the adhesive layer 21 may be formed of poly dimethyl siloxane (PDMS) or siloxane and is provided to facilitate adhesion between the oxygen permeable barrier layer 20 and the base film 10.

Hereinafter, the present invention will be described in detail with reference to Examples, but the present invention is not limited thereto.

### INVENTIVE EXAMPLE 1

DLC was deposited on a polyethylene layer by a plasma enhanced chemical vapor deposition (PECVD) method, a photo-polymerizable monomer, a photo-polymerization initiator, other additives, and the like were dissolved in a solvent in a fusion tank to thereby prepare a photosensitive resin layer. Then, the photosensitive resin layer and a polyethylene terephthalate (PET) layer were sequentially laminated, thereby manufacturing a dry film photoresist.

The PET layer or the PE layer of the dry film photoresist was exposed to UV light for 10 minutes, and then the degrees of curing of upper and lower portions of the dry film photoresist were measured. The result is shown in the following Table 1.

TABLE 1

| | Degree of Curing | Degree of Curing |
|---|---|---|
| | of Upper Portion | of Lower Portion |
| | (PET) | (PE) |
| Case of Exposing PET Layer to | 86% | 72% |
| UV Light | | |
| Case of Exposing PE Layer to UV | 85% | 76% |
| Light | | |

As shown in Table 1, when the PET layer of the dry film photoresist was exposed to UV light for 10 minutes and then the degrees of curing of the upper and lower portions were measured, the degree of curing of the upper portion (PET) was 86%, and the degree of curing of the lower portion (PE) was 72%.

In addition, when the PE layer of the dry film photoresist was exposed to UV light for 10 minutes and then the degrees of curing of the upper and lower portions were measured, the degree of curing of the upper portion (PET) was 85%, and the degree of curing of the lower portion (PE) was 76%.

Therefore, it may be appreciated that in the case in which the dry film photoresist includes the oxygen permeable barrier layer, a difference in the degrees of curing between the upper and lower portions was about 10%, which was decreased to be less than about 20% in the case in which the existing dry film photoresist does not include the oxygen permeable barrier layer.

### COMPARATIVE EXAMPLE 1

A photo-polymerizable monomer, a photo-polymerization initiator, other additives, and the like, were dissolved in a solvent in a fusion tank to thereby prepare a photosensitive resin layer. Then, the photosensitive resin layer and a polyethylene terephthalate (PET) layer were sequentially laminated on a polyethylene layer, thereby manufacturing a dry film photoresist.

The PET layer or the PE layer of the dry film photoresist was exposed to UV light for 10 minutes, and then the degrees of curing of upper and lower portions of the dry film photo resist were measured. The result is shown in the following Table 2.

TABLE 2

| | Degree of Curing of | Degree of Curing of |
|---|---|---|
| | Upper Portion (PET) | Lower Portion (PE) |
| Case of Exposing PET | 85% | 89% |
| Layer to UV Light | | |
| Case of Exposing PE | 62% | 69% |
| Layer to UV Light | | |

As shown in Table 2, when the PET layer of the dry film photoresist was exposed to UV light for 10 minutes and then the degrees of curing of the upper and lower portions were measured, the degree of curing of the upper portion (PET) was 85%, and the degree of curing of the lower portion (PE) was 89%.

In addition, when the PE layer of the dry film photoresist was exposed to UV light for 10 minutes and then the degrees of curing of the upper and lower portions were measured, the degree of curing of the upper portion (PET) was 62%, and the degree of curing of the lower portion (PE) was 69%.

Therefore, it may be appreciated that in the case in which the dry film photoresist does not include the oxygen permeable barrier layer, a difference in the degrees of curing between the upper and lower portions was about 20%, which was significantly larger than about 10% in the case in which the dry film photoresist includes the oxygen permeable barrier layer as in the present invention.

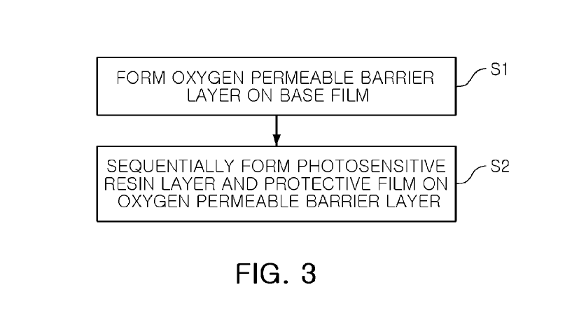

FIG. 3 is a flowchart showing a manufacturing method of a dry film photoresist 100 according to an embodiment of the present invention.

A manufacturing method of a dry film photoresist may include: forming an oxygen permeable barrier layer 20 on a base film 10 (S1); and sequentially forming a photosensitive resin layer 30 and a protective film 40 on the oxygen permeable barrier layer 20 (S2) as shown in FIG. 3.

The oxygen permeable barrier layer 20 may be formed of diamond-like carbon (DLC) or ethylene vinyl acetate (EVA).

Generally, in the forming of the oxygen permeable barrier layer 20 on the base film 10 (S1), diamond-like carbon (DLC) or ethylene vinyl acetate (EVA), the material of the oxygen permeable barrier layer 20, may be formed by deposition using a plasma enhanced chemical vapor deposition (PECVD) method, an ion beam sputtering deposition method, an ion beam deposition method, a laser ablation method, a filtered vacuum arc (FVA) method, or the like.

The PECVD may perform deposition on a polymer substrate at room temperature, and perform uniform deposition on a large area, even in the case of a flexible substrate.

In addition, the EVA may be formed by an adhesion method or an extrusion method as well as the deposition method.

The adhesion method is additionally performed to add the adhesive layer 21 in order to facilitate adhesion between the base film 10 and the EVA, and the extrusion method is performed by simultaneously extruding the base film and the EVA using heat in order to prevent infiltration of air. The adhesion method or the extrusion method has an advantage that a film manufactured in advance may be used, but production time may be increased.

As set forth above, according to embodiments of the present invention, a dry film photoresist includes an oxygen permeable barrier layer formed on a base film to prevent a curing reaction from being deteriorated by oxygen permeation in the dry film photoresist, such that residue that is not peeled off may be decreased, thereby significantly decreasing process defects.

While the present invention has been shown and described in connection with the embodiments, it will be apparent to those skilled in the art that modifications and variations can be made without departing from the spirit and scope of the invention as defined by the appended claims.

What is claimed is:

1. A dry film photoresist comprising:
a base film having an oxygen permeable barrier layer formed thereon;
a photosensitive resin layer formed on the oxygen permeable barrier layer; and
a protective film formed on the photosensitive resin layer.

2. The dry film photoresist of claim 1, wherein oxygen permeability of the oxygen permeable barrier layer is less than 0.1.

3. The dry film photoresist of claim 1, wherein the oxygen permeable barrier layer is formed of diamond-like carbon (DLC).

4. The dry film photoresist of claim 1, wherein the oxygen permeable barrier layer is formed of ethylene vinyl acetate (EVA).

5. The dry film photoresist of claim 1, wherein the base film is formed of polyethylene (PE).

6. The dry film photoresist of claim 1, wherein the photosensitive resin layer includes at least one selected from a group consisting of a polymer binder, a monomer, a photo-initiator, a thermal polymerization inhibitor, a polymerization accelerator, and a plasticizer.

7. The dry film photoresist of claim 1, wherein the protective film is formed of polyethylene terephthalate (PET).

8. A manufacturing method of a dry film photoresist, the manufacturing method comprising:
forming an oxygen permeable barrier layer on a base film; and
sequentially forming a photosensitive resin layer and a protective film on the oxygen permeable barrier layer.

9. The manufacturing method of claim 8, wherein oxygen permeability of the oxygen permeable barrier layer is less than 0.1.

10. The manufacturing method of claim 8, wherein the forming of the oxygen permeable barrier layer is performed by a deposition method.

11. The manufacturing method of claim 8, wherein the oxygen permeable barrier layer is formed of diamond-like carbon (DLC).

12. The manufacturing method of claim 8, wherein the oxygen permeable barrier layer is formed of ethylene vinyl acetate (EVA).

13. The manufacturing method of claim 12, wherein the EVA is formed by an adhesion method or an extrusion method.

14. The manufacturing method of claim 13, wherein the adhesion method is performed using poly dimethyl siloxane (PDMS) or siloxane.

15. The manufacturing method of claim 8, wherein the base film is formed of polyethylene (PE).

16. The manufacturing method of claim 8, wherein the photosensitive resin layer includes at least one selected from a group consisting of a polymer binder, a monomer, a photo-initiator, a thermal polymerization inhibitor, a polymerization accelerator, and a plasticizer.

17. The manufacturing method of claim 8, wherein the protective film is formed of polyethylene terephthalate (PET).
